(19) United States
(12) Patent Application Publication
(10) Pub. No.: US 2026/0300136 A1
(43) Pub. Date: Oct. 1, 2026

(54) Auto-Compensating Pipeline Architecture

(71) Applicant: QUALCOMM Incorporated, San Diego, CA (US)

(72) Inventors: Himanshu ARORA, GHAZIABAD (IN); Tanya JHA, Gorakhpur (IN); Maxwin Davis VALLULLY, Bangalore (IN); Sreenath ARIYOOR KORATT, Bangalore (IN); Kavya Sri GANGISHETTI, Warangal (IN)

(21) Appl. No.: 19/090,196

(22) Filed: Mar. 25, 2025

(51) Int. Cl. G06F 11/362

(52) U.S. Cl. CPC G06F 11/3636; G06F 11/3632

(57) ABSTRACT

A system is provided with various trace destinations that timestamp data and/or instructions to provide timestamped information that is used by a debugging tool to debug the system. Each trace destination receives a timestamp from an auto-compensating propagation path that increments the timestamp responsive to the number of pipeline stages in the auto-compensating propagation path.

### TECHNICAL FIELD

The present application relates generally to a pipeline architecture, and more particularly to an auto-compensating pipeline architecture.

### BACKGROUND

Various debug and trace architectures have been developed for system-on-a-chip (SoC) and related systems so that a designer may identify and fix program bugs. One key to debugging program execution is to timestamp events so that it is known when and how long events such as instructions take. For example, in ARM-based architectures, a system timer (which may also be denoted as a timestamp generator) may be used to generate a rolling 64-bit timestamp. When an event occurs, a timestamp consumer may record the current value of the 64-bit timestamp as either a timestamp itself or as the basis for an interpolated timestamp.

The system timer may also be denoted herein as a counter because it increments the rolling 64-bit time starting from zero responsive to cycles of a system clock signal. The rolling 64-bit time will thus also be denoted herein as a count. Depending upon the implementation, the count may be distributed directly or may instead be encoded into an encoded count. Regardless of whether a count is encoded or not, it may need to couple from one clock domain to another through a bridge. Once at a timestamp consumer, the count is recorded as a timestamp. Should the count have been encoded, the resulting timestamp may be denoted as a narrow timestamp. Regardless of whether encoding or interpolation is used, contemporaneous events should have the same timestamp so that correlation between events occurring at the same time is not lost.

### SUMMARY

In accordance with an aspect of the disclosure, a system is provided that includes: a timer configured to increment a timestamp responsive to a clock signal; and a first propagation path coupled between the timer and a first trace destination and including a plurality of P first pipeline stages arranged in a series, wherein P is a plural positive integer, each first pipeline stage in the plurality of P first pipeline stages being configured to register the timestamp responsive to the clock signal, and wherein the first propagation path is configured to increment the timestamp to provide an incremented version of the timestamp that is incremented by P bits to the first trace destination.

In accordance with another aspect of the disclosure, a system is provided that includes: a timer configured to increment a timestamp responsive to a clock signal; and a first propagation path coupled between the timer and a first trace destination and including at least one incrementing pipeline stage that includes: a first start of frame register configured to register a start of frame bit responsive to the clock signal to provide a registered start of frame signal that is asserted to indicate a start of frame of the timestamp; a multiplexer configured to select for a binary one input bit responsive to an assertion of the registered start of frame signal to form a binary multiplexer output signal; an adder configured to add the timestamp with the binary multiplexer output signal to form a summed output bit; and a first timestamp register configured to register the summed output bit responsive to the clock signal to form an incremented timestamp.

Finally, in accordance with yet another aspect of the disclosure, a method of debugging a system is provided that includes: generating a timestamp in a counter responsive to a first cycle of a clock signal; shifting the timestamp through a plurality of P registers arranged in a series between the counter and a trace destination during P additional cycles of the clock signal following the first cycle, wherein N is a plural positive integer; and incrementing the timestamp by P during the shifting of the timestamp through the plurality of P registers so that the trace destination receives an incremented version of timestamp.

These and other advantageous features may be better appreciated through the following detailed description.

### BRIEF DESCRIPTION OF THE DRAWINGS

FIG. 1 illustrates the timestamp propagation paths for a system having a conventional debugging architecture.

FIG. 2 illustrates a system having auto-compensating timestamp propagation paths for the debugging of the system in accordance with an aspect of the disclosure.

FIG. 3 illustrates a non-incrementing pipeline stage for the system of FIG. 2 in accordance with an aspect of the disclosure.

FIG. 4 illustrates an incrementing pipeline stage for the system of FIG. 2 in accordance with an aspect of the disclosure.

FIG. 5 illustrates a first propagation path in accordance with an aspect of the disclosure.

FIG. 6 illustrates a second propagation path in accordance with an aspect of the disclosure.

FIG. 7 illustrates a flowchart for a method of debugging a system including timestamp propagation paths in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Modern SoCs may have many millions of transistors. The resulting size of an SoC presents an issue with respect to using trace for debugging the SoC because of varying propagation delays between the system timer generating a rolling count that functions as a timestamp and trace destinations that time events responsive to the timestamp. In the following discussion, it will be assumed that the timestamp is formed as a 64-bit rolling count, but it will be appreciated that other bit sizes of the rolling count may be used in alternative implementations. With the timestamp generated by a system timer responsive to cycles of a system clock signal, the timestamp is then distributed across the SoC to various trace destinations through corresponding pipeline stages. Each pipeline stage registers the timestamp responsive to the system clock signal such that the registration of the timestamp in the pipeline state introduces a delay of one cycle of the system clock signal. If a propagation path has only one pipeline stage, then the propagation delay between the generation of the timestamp by the system timer and the receipt of timestamp at the trace destination is one clock cycle. Similarly, if a propagation path has only two pipeline stages, then the total propagation delay between the generation of the timestamp by the system timer and the receipt of timestamp at the trace destination is two clock cycles. More generally, if a propagation path extends through N pipeline stages (N being a plural positive integer), then the total propagation delay between the generation of the timestamp by the system timer and the receipt of timestamp at the trace destination is N clock cycles.

A propagation path to a first trace destination that is relatively close to the system timer may have just one pipeline stage that introduces a one-cycle delay with respect to the system clock signal. Similarly, the pipeline to a second trace destination that is more remote from the system time may include a serial pair of pipeline stages that introduces a two-cycle delay with respect to the system clock signal. The timestamp to the second trace destination is thus delayed by two clock cycles with respect to the current system clock cycle. The first and second trace destinations would then time an event such as a data transaction or an instruction execution with the same timestamp, yet the events are not simultaneous. The proper correlation between the respective events at the first and second trace destinations is thus lost.

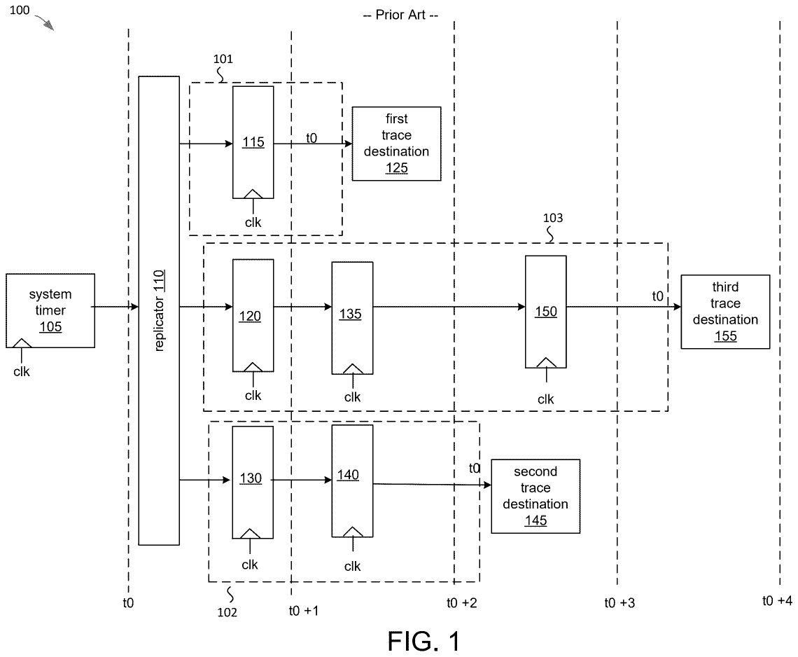

The problem raised by the varying propagation delays may be better appreciated through a consideration of an example system 100 shown in FIG. 1. A system timer 105 generates a timestamp as a rolling count responsive to cycles of a system clock signal (clk). The rolling count or timestamp has a current value of t0 responsive to a current cycle of the system clock signal. A replicator 110 replicates the timestamp of t0 into replicated timestamps for various propagation paths that are pipelined using pipeline stages. For example, the replicator 110 may replicate the rolling count of t0 into a propagation path 101 pipelined by a pipeline stage 115 to a first trace destination 125 that is also denoted herein as a local timestamp consumer. The pipeline stage 115 registers the timestamp of t0 responsive to a subsequent cycle (t0+1) of the system clock signal. The first trace destination 125 may thus timestamp an event with the timestamp of t0 from the register 115 during the t0+1 cycle of the system clock signal.

The replicator 105 also replicates the timestamp of t0 into a propagation path 102 that is pipelined through a serial pair of pipeline stages 130 and 140. The pipeline stage 130 is the first pipeline stage in the propagation path 102 and thus functions analogously to the register 115 to register the timestamp of t0 during the t0+1 cycle. The pipeline stage 140 is the second pipeline stage in the propagation path 102 such that it registers the timestamp of t 0 during a t0+2 cycle of the system clock signal. A second trace destination (local timestamp consumer) 145 may thus timestamp an event with the timestamp of t0 from the pipeline stage 140 during the t0+2 cycle of the system clock signal.

In addition, the replicator 105 also replicates the timestamp of t0 into a propagation path 103 that is pipelined through a serial arrangement of three pipeline stages 120, 135, and 150. The pipeline stage 120 is the first pipeline stage in the propagation path 103 and thus functions analogously to the pipeline stage 115 to register the timestamp of t0 during the t0+1 cycle. The pipeline stage 135 is the second pipeline stage in the propagation path 103 so it registers the timestamp of t0 during the t0+2 cycle of the system clock signal. Similarly, the pipeline stage 150 is the third pipeline stage in the propagation path 103 so it registers the timestamp of t0 during a t0+3 cycle of the system clock signal. A third trace destination (local timestamp consumer) 155 may thus timestamp an event with the timestamp of t0 from the register 150 during the t0+3 cycle of the system clock signal.

A debugging tool (not illustrated) that receives debug information from the trace destinations 125, 145, and 155 will then receive the same timestamp t0 for the corresponding trace events. However, the events were not simultaneous but instead occurred during distinct cycles of the system clock signal. In particular, the event for the first trace destination 125 occurred during the t0+1 system clock cycle whereas the event for the second trace destination 145 occurred during the t0+2 system clock cycle. Finally, the event for the third trace destination 155 occurred during the t0+3 system clock cycle. The debugging tool or infrastructure will thus have an erroneous time correlation for the events such that the debugging itself may become erroneous. An erroneous time correlation may thus occur whenever the timestamp is replicated over propagation paths that are pipelined by different numbers of pipeline stages.

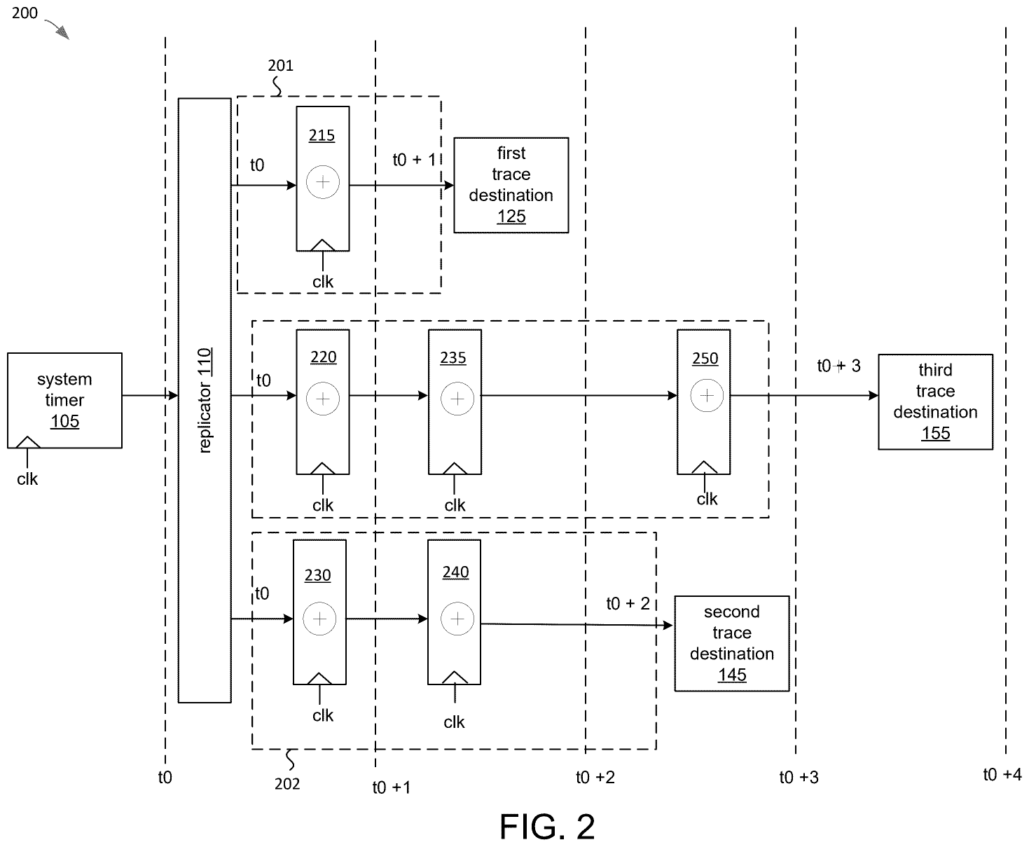

A system such as an SoC is disclosed herein in which the timestamp may be replicated over a plurality of improved propagation paths that are pipelined by differing numbers of pipeline stages, yet the timestamps are correctly correlated with each other. Each improved propagation path is configured to increment the timestamp by the number of pipeline stages that pipeline the timestamp. An example system 200 is shown in FIG. 2 that includes three improved propagation paths 201, 202, and 203. The system timer 105, the replicator 110, the first trace destination 125, the second trace destination 145, and the third trace destination 155 function as discussed for system 100. Each propagation path is configured to increment the timestamp responsive to the number of pipeline stages within the propagation path. Path 201 is analogous to path 101 in that it couples between the replicator 110 and the first trace destination 125 and includes just one pipeline stage 215. Since the pipelining of the timestamp t through the pipeline stage 215 introduces a propagation delay of one cycle of the system clock signal, the pipeline stage 215 is modified to not only register the timestamp but also to increment the timestamp to by one least-significant bit (LSB) to become t0+1. The first trace destination 125 will thus stamp its event with the timestamp of t0+1.

The propagation path 202 is analogous to path 102 in that it couples between the replicator 110 and the second trace destination 145 and includes a serial pair of pipeline stages 230 and 240. The registration of the timestamp to in the pipeline stages 230 and 240 introduces a propagation delay of two cycles of the system clock signal. In one implementation, the pipeline stage 230 and the pipeline stage 240 each not only registers the timestamp but also increments the timestamp by one LSB such that the second trace destination 145 stamps its event with a timestamp of t0+2 instead of t0. Alternatively, just one of the pipeline stages such as pipeline stage 240 may increment the timestamp by two LSBs as will be explained further herein.

The propagation path 203 is analogous to path 103 in that the path 203 couples between the replicator 110 and the third trace destination 155 and includes a serial combination of pipeline stages 220, 235, and 250. The registration of the timestamp t0 through the pipeline stages 220, 235, and 250 introduces a propagation delay of three cycles of the system clock signal. In one implementation, each pipeline stage 220, 235, and 250 not only registers the timestamp but also increments the timestamp by one LSB such that the third trace destination 155 stamps its event with a timestamp of t0+3 instead of t0. Alternatively, just one of the pipeline stages such as the pipeline stage 250 may increment the timestamp by three LSBs as will be explained further herein.

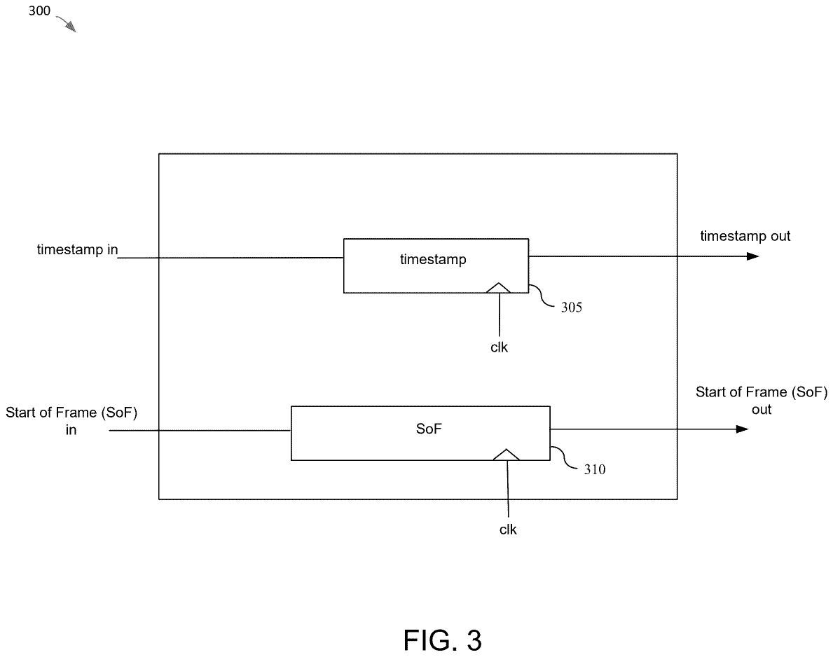

Although the timestamp is sent serially by the system timer, the serial propagation of the timestamp may be more than one bit wide. For example, in one implementation, each propagation path may propagate two bits of the timestamp responsive to a cycle of the system clock signal. Regardless of the bit width of the serial propagation, the serial propagation begins with the least significant bit (LSB) of the timestamp. To signal to a trace destination that the LSB is being transmitted, the system timer 105 (or another suitable source such a processor) may also transmit a start-of-frame (SoF) bit that is asserted in the same system clock cycle in which the LSB is transmitted into a propagation path. Referring again to system 100, each pipeline stage may thus include two registers—one register to register the timestamp and another register to register the SOF bit. An example non-incrementing pipeline stage 300 is shown in FIG. 3. Should the non-incrementing pipeline stage 300 be the first pipeline stage in its propagation path, a start of frame (SoF) register 310 registers a start of frame bit (start of frame in) from the system timer 105 or another suitable source. If the non-incrementing pipeline stage 300 is not the first pipeline stage, then the SoF register 310 receives the start of frame input bit from the preceding pipeline stage. Similarly, a timestamp register 305 in the non-incrementing pipeline stage 300 registers an input timestamp (timestamp in) from the system timer 105 or other suitable source should the non-incrementing pipeline stage 300 be the initial pipeline stage. If, however, the non-incrementing pipeline stage 300 is not the initial pipeline stage in the propagation path, then the timestamp register 305 receives the input timestamp from a preceding pipeline stage. The timestamp register 305 registers the input timestamp responsive to the system clock signal to provide a timestamp output (timestamp out). If the non-incrementing pipeline stage 300 is the final pipeline stage, then the timestamp out is provided to the corresponding trace destination. If there is a subsequent pipeline stage to the non-incrementing pipeline stage 300, then the timestamp output is provided as the timestamp input to the subsequent pipeline stage.

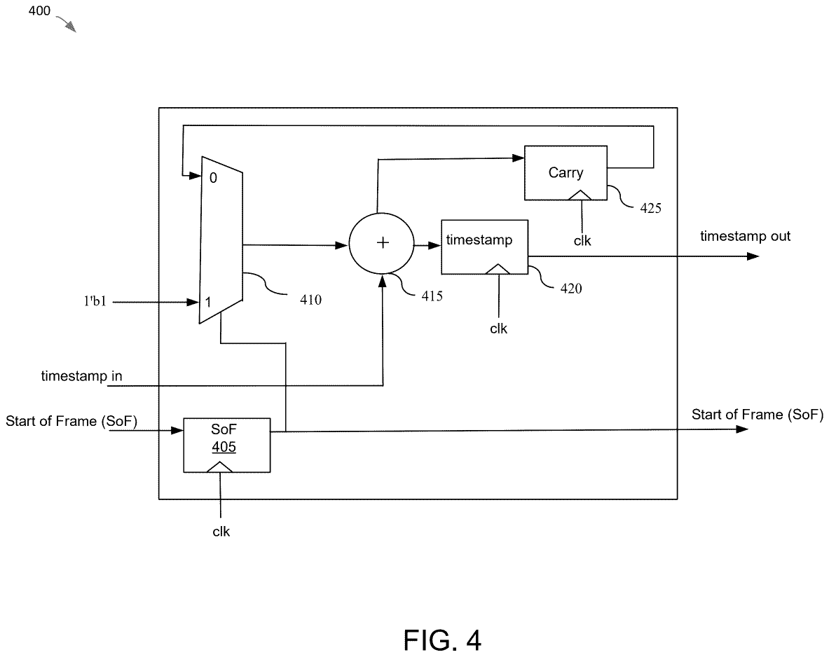

The transmission of the timestamp over the improved propagation paths disclosed herein is a serial transmission but it may occur over more than one bit per system clock cycle. For example, two bits per clock cycle may be sent in parallel over a propagation path in some implementations. More generally, N bits per clock cycle may be transmitted in parallel over a propagation path in some implementations, where N is a plural positive integer. Consider an implementation in which the timestamp is transmitted serially one bit at a time. The bit-width of the timestamp propagation is thus one bit in such an implementation (N=1). Each pipeline stage may be an incrementing pipeline stage with the incrementing being with respect to the LSB. An example incrementing pipeline stage 400 is shown in FIG. 4. Should the incrementing pipeline stage 400 be the first pipeline stage in the propagation path, a start of frame (SoF) register 405 registers a start of frame bit from the system timer 105 (or another suitable source). If the incrementing pipeline stage 400 is not the first pipeline stage in its propagation path, then the SoF register 405 receives the start of frame bit from the preceding pipeline stage. Similarly, the incrementing pipeline stage 400 receives an input timestamp (timestamp in) from the system timer 105 should the incrementing pipeline stage 400 be the initial pipeline stage. If, however, the incrementing pipeline stage is not the initial pipeline stage in the propagation path, then the incrementing pipeline stage 400 receives the timestamp in from a preceding pipeline stage.

The SoF bit (which is also denoted herein as a registered start of frame signal) controls a multiplexer 410 to select for an LSB binary one bit (1′b1) if the registered SoF bit from the SoF register 405 is a binary one. The selection by the multiplexer 410 forms a multiplexer output signal that is also denoted herein as a binary multiplexer output signal. An adder 415 adds the LSB bit with the LSB of the timestamp in to produce a summed output bit that is registered in a timestamp register 420 responsive to the system clock signal to form a corresponding timestamp bit. A carry register 425 registers a carry bit from the addition responsive to the system clock signal. The multiplexer 410 selects for the carry bit from the carry register 425 when the start of frame bit is not asserted. For example, suppose that the LSB of the timestamp is a binary one. The addition of the LSB of the timestamp in with the LSB binary one bit will thus produce a carry bit equaling a binary 1 that is then added with the next-to-LSB of the input timestamp in the subsequent clock cycle.

Referring again to the pipeline stages of FIG. 2, it may be appreciated that each pipeline stage may be constructed as shown for the incrementing pipeline stage 400. It doesn't matter how many incrementing pipeline stages are used, the resulting timestamp to the corresponding trace destination will be auto-compensated according to the number of incrementing pipeline stages. But the auto-compensation of the timestamp through the propagation path may be optimized with respect to reducing the number of incrementing pipeline stages such that non-incrementing pipeline stages may instead be used.

To reduce the number of incrementing pipeline stages for an N-bit-wide serial propagation of the timestamp through P pipeline stages, where N and P are both positive integers, the location of the incrementing pipeline stages can be shown to depend upon whether P is less than or greater than 2^{N}. If P is less than 2^{N}, then all the pipeline stages are non-incrementing except for the Pth stage being an incrementing pipeline stage that adds P to the timestamp. Conversely if P is greater than 2^{N}, then at every 2^{N} stages starting from the system timer the pipeline stage is an incrementing pipeline stage that adds 2^{N} to the timestamp and also the Pth (final) pipeline stage is an incrementing pipeline stage that adds 2^{N} to the timestamp. All the remaining pipeline stages may be non-incrementing pipeline stages. Referring again to FIG. 4, it may be seen that the incrementing pipeline stage 400 may be generalized into one that adds P or 2^{N} to the timestamp by changing the 1′b1value to the multiplexer 410 to be P or 2^{N}, respectively.

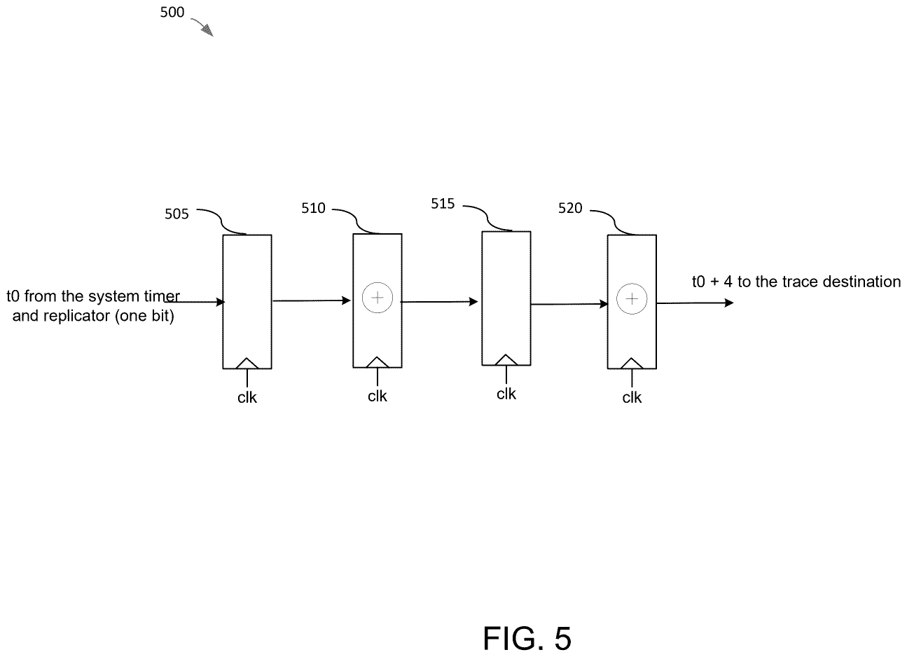

An example propagation path 500 in which N is one and P is four is shown in FIG. 5. In this case, 2^{N} is 2. Since P is greater than 2, an incrementing pipeline stage 220 that adds two is inserted at the 2¹ stage (the second stage) and at the 2² stage (the fourth stage 520). An initial pipeline stage 505 and a third pipeline stage 515 are non-incrementing pipeline stages as discussed for the non-incrementing pipeline stage 300. A timestamp t0 from the system timer and replicator is thus auto-compensated by the propagation path 500 to be t0+4 for the trace destination (not illustrated).

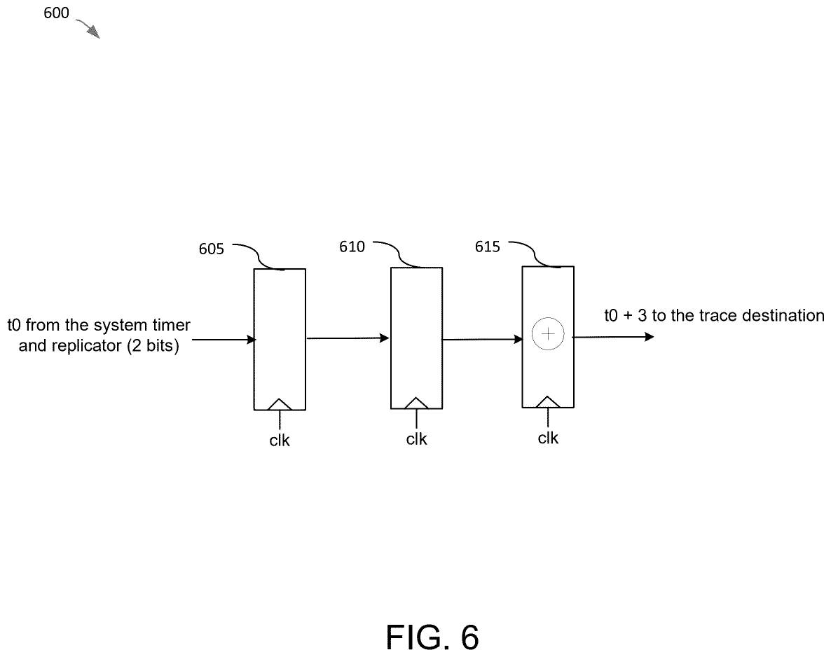

An example propagation path 600 in which N is two and P is three is shown in FIG. 6. In this case, 2^{N} is 4. Since P is less than 4, a third incrementing pipeline stage 615 that adds three to the timestamp is inserted for the Pth (third) pipeline stage. A first pipeline stage 605 and a second pipeline stage 610 are both non-incrementing pipeline stages such as discussed for the non-incrementing pipeline stage 300. A timestamp to from the system timer and replicator is thus auto-compensated by the propagation path 600 to be t0+3 for the trace destination (not illustrated).

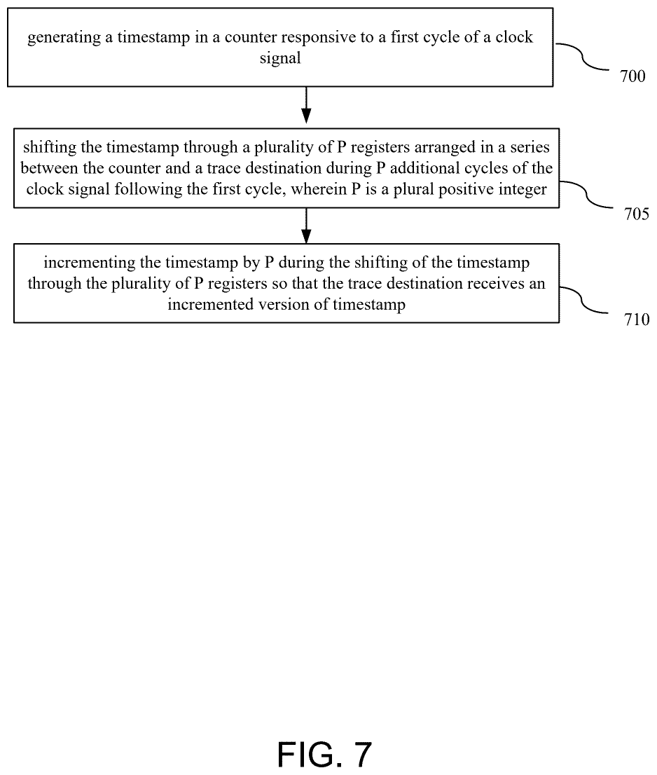

A debugging method using the timestamp propagation paths disclosed herein will now be discussed with respect to the flowchart of FIG. 7. The method includes an act 700 of generating a timestamp in a counter responsive to a first cycle of a clock signal. The generation of the timestamp for any of the propagation paths of FIGS. 2-6 is an example of act 700.

The method also includes an act 705 of shifting the timestamp through a plurality of P registers arranged in a series between the counter and a trace destination during P additional cycles of the clock signal following the first cycle, wherein P is a plural positive integer. The shifting of the timestamp through any of the propagation paths of FIGS. 2-6 is an example of act 705. The method further includes an act 710 of incrementing the timestamp by P during the shifting of the timestamp through the plurality of P registers so that the trace destination receives an incremented version of timestamp. The incrementing of the timestamp in the incrementing pipeline stage(s) of FIGS. 2-6 is an example of act 710.

The disclosure will now be summarized through the following numbered clauses:
Clause 1. a system comprising:
   a timer configured to increment a timestamp responsive to a clock signal; and
   a first propagation path coupled between the timer and a first trace destination and including a plurality of P first pipeline stages arranged in a series, wherein P is a plural positive integer, each first pipeline stage in the plurality of P first pipeline stages being configured to register the timestamp responsive to the clock signal, and wherein the first propagation path is configured to increment the timestamp to provide an incremented version of the timestamp that is incremented by P bits to the first trace destination.
Clause 2. The system of clause 1, wherein the plurality of P first pipeline stages comprises at least one incrementing pipeline stage that is configured to increment the timestamp to form the incremented version of the timestamp.
Clause 3. The system of clause 2, wherein the at least one incrementing pipeline stage comprises a plurality of P incrementing pipeline stages, and wherein each incrementing pipeline stage in the plurality of P incrementing pipeline stages is configured to increment the timestamp by one bit.
Clause 4. The system of any of clauses 2-3, wherein the plurality of P first pipeline stages further comprises at least one non-incrementing pipeline stage that does not increment the timestamp.
Clause 5. The system of clause 4, wherein the at least one incrementing pipeline stage and the at least one non-incrementing pipeline stage is each further configured to register a start of frame bit that is asserted simultaneously with a transmission of a least-significant bit of the timestamp into the first propagation path.
Clause 6. The system of any of clauses 1-5, further comprising:
   a replicator configured to replicate the timestamp from the timer into a replica timestamp; and
   a second propagation path coupled between the timer and a second trace destination and including a plurality of X second pipeline stages arranged in a series, wherein X is a plural positive integer, each second pipeline stage in the plurality of X second pipeline stages is configured to register the replica timestamp responsive to the clock signal, and the second propagation path is configured to increment the replica timestamp to provide an incremented version of the replica timestamp that is incremented by X bits to the second trace destination.
Clause 7. The system of any of clauses 1-6, wherein the system is integrated within a system-on-chip (SoC) integrated circuit.
Clause 8. The system of any of clauses 1-7, wherein the first trace destination is configured to timestamp data with the incremented version of the timestamp to provide timestamped data.
Clause 9. The system of clause 8, further comprising: a debugging tool configured to debug the system responsive to the timestamped data.
Clause 10. a system, comprising:
   a timer configured to increment a timestamp responsive to a clock signal; and
   a first propagation path coupled between the timer and a first trace destination and including at least one incrementing pipeline stage that includes:
      a first start of frame register configured to register a start of frame bit responsive to the clock signal to provide a registered start of frame signal that is asserted to indicate a start of frame of the timestamp;
      a multiplexer configured to select for a binary one input bit responsive to an assertion of the registered start of frame signal to form a binary multiplexer output signal;
      an adder configured to add the timestamp with the binary multiplexer output signal to form a summed output bit; and
      a first timestamp register configured to register the summed output bit responsive to the clock signal to form an incremented timestamp.
Clause 11. The system of clause 10, wherein the at least one incrementing pipeline stage further includes:
   a carry register configured to register a carry bit from the adder responsive to the clock signal, wherein the multiplexer is further configured to select for the carry bit to form the binary multiplexer output signal responsive to a de-assertion of the registered start of frame signal.
Clause 12. The system of any of clauses 10-11, wherein the at least one incrementing pipeline stage comprises a plurality of incrementing pipeline stages arranged in a series, and wherein a successive incrementing pipeline stage in the plurality of incrementing pipeline stages is configured to increment the incremented timestamp from a preceding incrementing pipeline stage in the plurality of incrementing pipeline stages.
Clause 13. The system of any of clauses 10-12, wherein the first propagation path further comprises at least one non-incrementing pipeline stage that includes:
   a second start of frame register configured to register the start of frame bit.
Clause 14. The system of clause 13, wherein the at least one non-incrementing pipeline stage further includes:
   a second timestamp register configured to register the timestamp responsive to the clock signal.
Clause 15. The system of clause 14, wherein the at least one non-incrementing pipeline stage comprises a plurality of non-incrementing pipeline stages arranged in a series.
Clause 16. A method of debugging a system, comprising:
   generating a timestamp in a counter responsive to a first cycle of a clock signal;
   shifting the timestamp through a plurality of P registers arranged in a series between the counter and a trace destination during P additional cycles of the clock signal following the first cycle, wherein P is a plural positive integer; and
   incrementing the timestamp by P during the shifting of the timestamp through the plurality of P registers so that the trace destination receives an incremented version of timestamp.
Clause 17. The method of clause 16, further comprising:
   timestamping data at the trace destination with the incremented version of the timestamp to provide timestamped data.
Clause 18. The method of clause 17, further comprising:
   debugging the system responsive to the timestamping data.
Clause 19. The method of any of clauses 16-18, wherein incrementing the timestamp comprises incrementing the timestamp by P in one adder.
Clause 20. The method of any of clauses 16-18, wherein incrementing the timestamp comprises incrementing the timestamp by one in P adders.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A system comprising:
a timer configured to increment a timestamp responsive to a clock signal; and
a first propagation path coupled between the timer and a first trace destination and including a plurality of P first pipeline stages arranged in a series, wherein P is a plural positive integer, each first pipeline stage in the plurality of P first pipeline stages being configured to register the timestamp responsive to the clock signal, and wherein the first propagation path is configured to increment the timestamp to provide an incremented version of the timestamp that is incremented by P bits to the first trace destination.

2. The system of claim 1, wherein the plurality of P first pipeline stages comprises at least one incrementing pipeline stage that is configured to increment the timestamp to form the incremented version of the timestamp.

3. The system of claim 2, wherein the at least one incrementing pipeline stage comprises a plurality of P incrementing pipeline stages, and wherein each incrementing pipeline stage in the plurality of P incrementing pipeline stages is configured to increment the timestamp by one bit.

4. The system of claim 2, wherein the plurality of P first pipeline stages further comprises at least one non-incrementing pipeline stage that does not increment the timestamp.

5. The system of claim 4, wherein the at least one incrementing pipeline stage and the at least one non-incrementing pipeline stage is each further configured to register a start of frame bit that is asserted simultaneously with a transmission of a least-significant bit of the timestamp into the first propagation path.

6. The system of claim 1, further comprising:
a replicator configured to replicate the timestamp from the timer into a replica timestamp; and
a second propagation path coupled between the timer and a second trace destination and including a plurality of X second pipeline stages arranged in a series, wherein X is a plural positive integer, each second pipeline stage in the plurality of X second pipeline stages is configured to register the replica timestamp responsive to the clock signal, and the second propagation path is configured to increment the replica timestamp to provide an incremented version of the replica timestamp that is incremented by X bits to the second trace destination.

7. The system of claim 1, wherein the system is integrated within a system-on-chip (SoC) integrated circuit.

8. The system of claim 1, wherein the first trace destination is configured to timestamp data with the incremented version of the timestamp to provide timestamped data.

9. The system of claim 8, further comprising: a debugging tool configured to debug the system responsive to the timestamped data.

10. A system, comprising:
a timer configured to increment a timestamp responsive to a clock signal; and
a first propagation path coupled between the timer and a first trace destination and including at least one incrementing pipeline stage that includes:
a first start of frame register configured to register a start of frame bit responsive to the clock signal to provide a registered start of frame signal that is asserted to indicate a start of frame of the timestamp;
a multiplexer configured to select for a binary one input bit responsive to an assertion of the registered start of frame signal to form a binary multiplexer output signal;
an adder configured to add the timestamp with the binary multiplexer output signal to form a summed output bit; and
a first timestamp register configured to register the summed output bit responsive to the clock signal to form an incremented timestamp.

11. The system of claim 10, wherein the at least one incrementing pipeline stage further includes:
a carry register configured to register a carry bit from the adder responsive to the clock signal, wherein the multiplexer is further configured to select for the carry bit to form the binary multiplexer output signal responsive to a de-assertion of the registered start of frame signal.

12. The system of claim 10, wherein the at least one incrementing pipeline stage comprises a plurality of incrementing pipeline stages arranged in a series, and wherein a successive incrementing pipeline stage in the plurality of incrementing pipeline stages is configured to increment the incremented timestamp from a preceding incrementing pipeline stage in the plurality of incrementing pipeline stages.

13. The system of claim 10, wherein the first propagation path further comprises at least one non-incrementing pipeline stage that includes:
a second start of frame register configured to register the start of frame bit.

14. The system of claim 13, wherein the at least one non-incrementing pipeline stage further includes:
a second timestamp register configured to register the timestamp responsive to the clock signal.

15. The system of claim 14, wherein the at least one non-incrementing pipeline stage comprises a plurality of non-incrementing pipeline stages arranged in a series.

16. A method of debugging a system, comprising:
generating a timestamp in a counter responsive to a first cycle of a clock signal;
shifting the timestamp through a plurality of P registers arranged in a series between the counter and a trace destination during P additional cycles of the clock signal following the first cycle, wherein P is a plural positive integer; and
incrementing the timestamp by P during the shifting of the timestamp through the plurality of P registers so that the trace destination receives an incremented version of timestamp.

17. The method of claim 16, further comprising:
timestamping data at the trace destination with the incremented version of the timestamp to provide timestamped data.

18. The method of claim 17, further comprising:
debugging the system responsive to the timestamping data.

19. The method of claim 16, wherein incrementing the timestamp comprises incrementing the timestamp by P in one adder.

20. The method of claim 16, wherein incrementing the timestamp comprises incrementing the timestamp by one in P adders.
